(19) United States
(12) Patent Application Publication
(10) Pub. No.: US 2026/0181777 A1
(43) Pub. Date: Jun. 25, 2026

(54) Pin Cutout in Memory Modules

(71) Applicant: Advanced Micro Devices, Inc., Santa Clara, CA (US)

(72) Inventors: Christopher Edward Cox, Placerville, CA (US); Bhyrav M Mutnury, Round Rock, TX (US); Ravi B Bingi, Austin, TX (US); Aaron John Nygren, Boise, ID (US)

(73) Assignee: Advanced Micro Devices, Inc., Santa Clara, CA (US)

(21) Appl. No.: 19/345,147

(22) Filed: Sep. 30, 2025

Related U.S. Application Data
(60) Provisional application No. 63/709,830, filed on Oct. 21, 2024.

(51) Int. Cl. H05K 1/11; H05K 1/18

(52) U.S. Cl. CPC H05K 1/117; H05K 1/18; H05K 2201/09409; H05K 2201/10159

(57) ABSTRACT

Systems and techniques for pin cutouts in memory modules (e.g., Dual In-line Memory Modules (DIMMs)) are described. A memory module includes one or more memory integrated circuits mounted on a printed circuit board. The memory module also includes at least one additional component, including, for example, a power manager integrated circuit, buffers, and inductors. The memory module also includes one or more rows of pins to provide an electrical connection to a motherboard. One or more rows include a pin cutout wherein some pins are removed or not placed in the row. The pin cutout allows a component to be mounted on the PCB in the foregone board area.

### CROSS-REFERENCE TO RELATED APPLICATION

This application claims priority to U.S. Provisional Ser. No. 63/709,830, filed Oct. 21, 2024, entitled “Pin Cutout in Dual In-line Memory Module (DIMM),” the content of which is incorporated herein by reference in its entirety.

### BACKGROUND

The evolution of memory technologies and standards, such as the progression through various generations of Double Data Rate (DDR) technology, has resulted in improvements in data transfer rates and overall system performance. These advancements, however, often necessitate changes in the physical design and electrical interfaces of memory modules. For example, the transition to newer DDR standards may result in additional signal lines, power connections, and/or connection pins.

Additional connection pins between memory modules and motherboards can be added to accommodate increased functionality within the constraints of existing form factors. One option is to add more pins by including one or more additional pin rows on a module's edge connector, thereby increasing pin density and improving signal integrity. Increasing the number of pins reduces the available space for other components, which can potentially affect the overall design and performance characteristics of memory modules.

### BRIEF DESCRIPTION OF THE DRAWINGS

FIG. 1 depicts a block diagram of a processing system configured to execute one or more applications in accordance with one or more implementations.

FIG. 2 depicts a non-limiting example of a pin cutout in a memory module.

FIG. 3 depicts a non-limiting example of multiple memory modules with pin cutouts in a stacked arrangement.

FIGS. 4A through 4C depict various views of example motherboard connectors to receive a memory module with a pin cutout.

### DETAILED DESCRIPTION

### Overview

Many computing devices, including desktop computers, laptops, servers, and workstations, use dual in-line memory modules (DIMMs) to increase their memory capacity. Each DIMM typically includes multiple memory integrated circuits (ICs) or chips mounted on a printed circuit board (PCB), which connects the memory chips to other components. These components include power management integrated circuits (PMICs), inductors, buffers, and additional supporting parts. The PCB also features a row of pins that connect the DIMM to memory slots on the motherboard, which can vary in number from one to four or more. more.

As the density and data transfer rates of memory chips improve and the number of memory chips on a DIMM increases, DIMMs will likely add one or more additional pin rows to enhance signal integrity between the DIMM and motherboard. The increased number of pins decreases the available space on the DIMM PCB for components.

The placement of components on memory modules balances electrical performance, thermal management, and manufacturing factors, with each component affecting module operation. For example, the PMIC manages voltage to the memory chips, and inductors filter electrical noise and stabilize power delivery. The placement of these and other larger components on the PCB can significantly influence the electrical performance and thermal characteristics of DIMMs.

When space is limited on one side of the PCB, conventional designs often place components on both sides of the board to maximize space utilization. For example, the extra pin rows may cause inductors (such as those near the PMIC) to be placed on the backside of the DIMM module. Alternatively, additional components might be added to the backside, increasing the vertical distance between stacked DIMMs to allow better airflow and heat dissipation.

In contrast, the techniques and systems described for a pin cutout in memory modules free up space for one or more components without requiring larger or taller components to be placed on the backside of the board. A cutout or notch is created in one or more pin rows by intentionally leaving gaps along the module's edge connector. For example, a small number of pins (e.g., about 15 pins) are removed from the second row near the center of the DIMM module to allow taller inductor components to partially hide in the shadow of the connector, reducing their impact on airflow around the DIMM. This can improve cooling in these often densely packed computing environments. The pin cutout provides dedicated space for specific components while preserving the overall form factor and compatibility with standard memory slots.

The cutout can remove pins from one or all pin rows in different implementations. For example, the cutout is positioned differently on the PCB or at multiple locations along the pin rows. Additionally, the described techniques suggest relocating the power pins to the center (e.g., near the power manager integrated circuit (PMIC)) to reduce the length of the input rails from the power pins to the PMIC.

The described pin cutout(s) allow DIMMs and other memory modules to reclaim some surface area on the PCB for larger components, helping to avoid placing these components on both faces of the PCB. Additionally, larger components like inductors can be partially hidden within the connector to reduce their impact on airflow and potentially simplify heat-spreader designs, as unhidden components can have similar heights, enabling tighter stacking of multiple DIMMs in memory-intensive systems. Lastly, relocating the power pins reduces the pin-to-PMIC power rail length by moving the power to the center pins. These benefits collectively lead to more efficient, higher-performing memory systems that better meet the demands of advanced computing applications while maintaining compatibility with existing form factors.

In some aspects, the described techniques and systems relate to a memory module comprising one or more memory integrated circuits mounted on a printed circuit board (PCB), one or more additional components mounted on the PCB, and one or more rows of pins to electrically connect the memory module to a motherboard, the one or more rows including a pin cutout that breaks the one or more rows, the pin cutout providing sufficient spacing on the PCB to mount at least one component on the PCB.

In some aspects, the described techniques and systems relate to a memory module wherein the PCB includes at least two rows of pins.

In some aspects, the described techniques and systems relate to a memory module wherein the pin cutout is provided in a single row of the at least two rows of pins.

In some aspects, the described techniques and systems relate to a memory module wherein the PCB includes at least three rows of pins, and the pin cutout extends across at least two of the at least three rows of pins.

In some aspects, the described techniques and systems relate to a memory module wherein the one or more rows include multiple pin cutouts.

In some aspects, the described techniques and systems relate to a memory module wherein the pin cutout is centrally located in relation to the one or more rows.

In some aspects, the described techniques and systems relate to a memory module wherein the memory module is a dual in-line memory module (DIMM).

In some aspects, the described techniques and systems relate to a memory module wherein the one or more memory integrated circuits comply with a double data rate six (DDR6) memory specification.

In some aspects, the described techniques and systems relate to a memory module wherein the pin cutout is configured to accommodate placement of at least one of the one or more additional components.

In some aspects, the described techniques and systems relate to a memory module wherein the one or more additional components positioned at least partially in the pin cutout includes one or more inductors.

In some aspects, the described techniques and systems relate to a memory module wherein the pin cutout is configured to accommodate the placement of the at least one of the one or more additional components to be partially recessed into a portion of a motherboard connector when the memory module is inserted into the motherboard connector.

In some aspects, the described techniques and systems relate to a memory module wherein the pin cutout has a variable width along the length of two or more rows of pins to accommodate the placement of different sizes or arrangements of the one or more additional components.

In some aspects, the described techniques and systems relate to a memory module wherein power pins are positioned near a lateral center of at least one of the one or more rows of pins to reduce a length of power rails from the power pins to a power management integrated circuit (PMIC).

In some aspects, the described techniques and systems relate to a motherboard connector comprising a housing configured to receive a memory module, a plurality of electrical contacts arranged in one or more rows within the housing, the electrical contacts configured to electrically engage with corresponding pins of the memory module, and a cutout region in at least one row of the electrical contacts, the cutout region configured to align with a pin cutout in a corresponding row of pins on the memory module when the memory module is inserted into the housing.

In some aspects, the described techniques and systems relate to a motherboard connector wherein the cutout region provides space to accommodate one or more components on the memory module.

In some aspects, the described techniques and systems relate to a motherboard connector wherein the cutout region provides space to accommodate an inductor on the memory module.

In some aspects, the described techniques and systems relate to a motherboard connector wherein the cutout region is positioned near a lateral center of the at least one row of electrical contacts.

In some aspects, the described techniques and systems relate to a motherboard connector wherein the plurality of electrical contacts are arranged in at least two rows, and a subset of electrical contacts in a first row are configured to provide power to the memory module and are positioned near a lateral center of the first row.

In some aspects, the described techniques and systems relate to a motherboard connector wherein the cutout region has a variable depth along the length of two rows of electrical contacts to accommodate components of different heights on the memory module.

In some aspects, the described techniques and systems relate to a system comprising one or more memory modules, each memory module including one or more memory integrated circuits mounted on a printed circuit board (PCB), one or more additional components mounted on the PCB, and one or more rows of pins for electrically connecting the memory module to a motherboard, the one or more rows including a pin cutout that discontinues the one or more rows, and one or more motherboard connectors of the motherboard, each motherboard connector including a housing configured to receive the memory module, a plurality of electrical contacts arranged in one or more rows within the housing, the electrical contacts configured to electrically engage with corresponding pins of the memory module, and a cutout region in at least one row of the electrical contacts, the cutout region configured to align with the pin cutout in a corresponding row of pins on the memory module when the memory module is inserted into the housing.

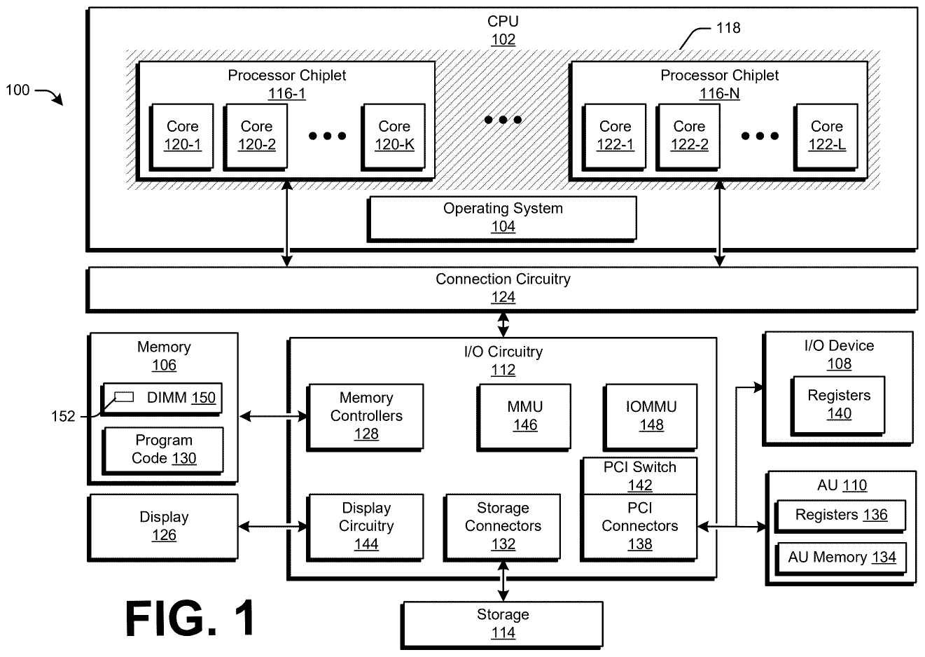

FIG. 1 is a block diagram of a processing system configured to execute one or more applications in accordance with one or more implementations. In particular, FIG. 1 includes a processing system 100 configured to execute one or more applications, such as computing applications (e.g., machine-learning applications, neural network applications, high-performance computing applications, databasing applications, gaming applications), graphics applications, and the like. Examples of devices in which the processing system 100 is implemented include but are not limited to a server computer, personal computer (e.g., desktop or tower computer), notebook computer, laptop computer, entertainment device (e.g., gaming console, television, set-top box), automotive computer or computer for another type of vehicle, networking device, medical device or system, and other computing devices or systems.

In the illustrated example, the processing system 100 includes a central processing unit (CPU) 102. In one or more implementations, the CPU 102 is configured to run an operating system (OS) 104 that manages the execution of applications. For example, the OS 104 is configured to schedule the execution of tasks (e.g., instructions) for applications, allocate portions of resources (e.g., system memory 106, CPU 102, input/output (I/O) device 108, accelerator unit (AU) 110, storage 114) for the execution of tasks for the applications, provide an interface to I/O devices (e.g., I/O device 108) for the applications, or any combination thereof.

The CPU 102 includes one or more processor chiplets 116, which are communicatively coupled by a data fabric 118 in one or more implementations. Each processor chiplet 116, for example, includes one or more processor cores 120, 122 configured to execute one or more series of instructions concurrently, also referred to herein as “threads” or workloads, for an application. Further, the data fabric 118 communicatively couples each processor chiplet 116-N of the CPU 102 such that each processor core (e.g., processor cores 120) of a first processor chiplet (e.g., 116-1) is communicatively coupled to each processor core (e.g., processor cores 122) of one or more other processor chiplets 116.

Though the example embodiment in FIG. 1 shows a first processor chiplet (116-1) having three processor cores (120-1, 120-2, 120-K) representing a K number of processor cores 122 and a second processor chiplet (116-N) having three processor cores (e.g., 122-1, 122-2, 122-L) representing an L number of processor cores 122, in other implementations (L being an integer number greater than or equal to one), each processor chiplet 116 may have any number of processor cores 120, 122. For example, each processor chiplet 116 can have the same number of processor cores 120, 122 as one or more other processor chiplets 116, a different number of processor cores 120, 122 as one or more other processor chiplets 116, or both.

Examples of connections that are usable to implement the data fabric 118 include but are not limited to buses (e.g., a data bus, a system, an address bus), interconnects, memory channels, and silicon vias, traces, and planes. Other example connections include optical connections, fiber optic connections, and/or connections or links based on quantum entanglement.

Additionally, within the processing system 100, the CPU 102 is communicatively coupled to an I/O circuitry 112 by a connection circuitry 124. For example, each processor chiplet 116 of the CPU 102 is communicatively coupled to the I/O circuitry 112 by the connection circuitry 124. The connection circuitry 124 includes, for example, one or more data fabrics, buses, buffers, queues, and the like. The I/O circuitry 112 is configured to facilitate communications between two or more components of the processing system 100 such as between the CPU 102, system memory 106, display 126, universal serial bus (USB) devices, peripheral component interconnect (PCI) devices (e.g., I/O device 108, AU 110), storage 114, and the like.

As an example, system memory 106 includes any combination of one or more volatile memories and/or one or more non-volatile memories, examples of which include dynamic random-access memory (DRAM), static random-access memory (SRAM), non-volatile RAM, and the like. To manage access to the system memory 106 by CPU 102, the I/O device 108, the AU 110, and/or any other components, the I/O circuitry 112 includes one or more memory controllers 128. The memory controllers 128, for example, include circuitry configured to manage and fulfill memory access requests issued from the CPU 102, the I/O device 108, the AU 110, or any combination thereof. Examples of such requests include read requests, write requests, fetch requests, pre-fetch requests, or any combination thereof. That is to say, the memory controllers 128 are configured to manage access to the data stored at one or more memory addresses within the system memory 106, such as by CPU 102, I/O device 108, and/or AU 110. In this example, the memory 106 includes one or more DIMMs 150 with one or more pin cutouts 152 to accommodate various components.

When an application is to be executed by processing system 100, the OS 104 running on the CPU 102 is configured to load at least a portion of program code 130 (e.g., an executable file) associated with the application from, for example, a storage 114 into system memory 106. This storage 114, for example, includes a non-volatile storage such as a flash memory, solid-state memory, hard disk, optical disc, or the like configured to store program code 130 for one or more applications.

To facilitate communication between the storage 114 and other components of processing system 100, the I/O circuitry 112 includes one or more storage connectors 132 (e.g., universal serial bus (USB) connectors, serial AT attachment (SATA) connectors, PCI Express (PCIe) connectors) configured to communicatively couple storage 114 to the I/O circuitry 112 such that I/O circuitry 112 is capable of routing signals to and from the storage 114 to one or more other components of the processing system 100.

In association with executing an application, in one or more scenarios, the CPU 102 is configured to issue one or more instructions (e.g., threads) to be executed for an application to the AU 110. The AU 110 is configured to execute these instructions by operating as one or more vector processors, coprocessors, graphics processing units (GPUs), general-purpose GPUs (GPGPUs), non-scalar processors, highly parallel processors, artificial intelligence (AI) processors (also known as neural processing units, or NPUs), inference engines, machine-learning processors, other multithreaded processing units, scalar processors, serial processors, programmable logic devices (e.g., field-programmable logic devices (FPGAs)), or any combination thereof.

In at least one example, the AU 110 includes one or more compute units that concurrently execute one or more threads of an application and store data resulting from the execution of these threads in AU memory 134. This AU memory 134, for example, includes any combination of one or more volatile memories and/or non-volatile memories, examples of which include caches, video RAM (VRAM), or the like. In one or more implementations, these compute units are also configured to execute these threads based on the data stored in one or more physical registers 136 of the AU 110.

To facilitate communication between the AU 110 and one or more other components of processing system 100, the I/O circuitry 112 includes or is otherwise connected to one or more connectors, such as PCI connectors 138 (e.g., PCIe connectors) each including circuitry configured to communicatively couple the AU 110 to the I/O circuitry such that the I/O circuitry 112 is capable of routing signals to and from the AU 110 to one or more other components of the processing system 100. Further, the PCIe connectors 138 are configured to communicatively couple the I/O device 108 to the I/O circuitry 112 such that the I/O circuitry 112 is capable of routing signals to and from the I/O device 108 to one or more other components of the processing system 100.

By way of example and not limitation, the I/O device 108 includes one or more keyboards, pointing devices, game controllers (e.g., gamepads, joysticks), audio input devices (e.g., microphones), touch pads, printers, speakers, headphones, optical mark readers, hard disk drives, flash drives, solid-state drives, and the like. Additionally, the I/O device 108 is configured to execute one or more operations, tasks, instructions, or any combination thereof based on one or more physical registers 140 of the I/O device 108. In one or more implementations, such physical registers 140 are configured to maintain data (e.g., operands, instructions, values, variables) indicating one or more operations, tasks, or instructions to be performed by the I/O device 108.

To manage communication between components of the processing system 100 (e.g., AU 110, I/O device 108) that are connected to PCI connectors 138, and one or more other components of the processing system 100, the I/O circuitry 112 includes PCI switch 142. The PCI switch 142, for example, includes circuitry configured to route packets to and from the components of the processing system 100 connected to the PCI connectors 138 as well as to the other components of the processing system 100. As an example, based on address data indicated in a packet received from a first component (e.g., CPU 102), the PCI switch 142 routes the packet to a corresponding component (e.g., AU 110) connected to the PCI connectors 138.

Based on the processing system 100 executing a graphics application, for instance, the CPU 102, the AU 110, or both are configured to execute one or more instructions (e.g., draw calls) such that a scene including one or more graphics objects is rendered. After rendering such a scene, the processing system 100 stores the scene in the storage 114, displays the scene on the display 126, or both. The display 126, for example, includes a cathode-ray tube (CRT) display, liquid crystal display (LCD), light emitting diode (LED) display, organic light emitting diode (OLED) display, or any combination thereof. To enable the processing system 100 to display a scene on the display 126, the I/O circuitry 112 includes display circuitry 144. The display circuitry 144, for example, includes high-definition multimedia interface (HDMI) connectors, DisplayPort connectors, digital visual interface (DVI) connectors, USB connectors, and the like, each including circuitry configured to communicatively couple the display 126 to the I/O circuitry 112. Additionally or alternatively, the display circuitry 144 includes circuitry configured to manage the display of one or more scenes on the display 126 such as display controllers, buffers, memory, or any combination thereof.

Further, the CPU 102, the AU 110, or both are configured to concurrently run one or more virtual machines (VMs), which are each configured to execute one or more corresponding applications. To manage communications between such VMs and the underlying resources of the processing system 100, such as any one or more components of processing system 100, including the CPU 102, the I/O device 108, the AU 110, and the system memory 106, the I/O circuitry 112 includes memory management unit (MMU) 146 and input-output memory management unit (IOMMU) 148. The MMU 146 includes, for example, circuitry configured to manage memory requests, such as from the CPU 102 to the system memory 106. For example, the MMU 146 is configured to handle memory requests issued from the CPU 102 and associated with a VM running on the CPU 102. These memory requests, for example, request access to read, write, fetch, or pre-fetch data residing at one or more virtual addresses (e.g., guest virtual addresses) each indicating one or more portions (e.g., physical memory addresses) of the system memory 106. Based on receiving a memory request from the CPU 102, the MMU 146 is configured to translate the virtual address indicated in the memory request to a physical address in the system memory 106 and to fulfill the request. The IOMMU 148 includes, for example, circuitry configured to manage memory requests (memory-mapped I/O (MMIO) requests) from the CPU 102 to the I/O device 108, the AU 110, or both, and to manage memory requests (direct memory access (DMA) requests) from the I/O device 108 or the AU 110 to the system memory 106. For example, to access the registers 140 of the I/O device 108, the registers 136 of the AU 110, and/or the AU memory 134, the CPU 102 issues one or more MMIO requests. Such MMIO requests each request access to read, write, fetch, or pre-fetch data residing at one or more virtual addresses (e.g., guest virtual addresses) which each represent at least a portion of the registers 140 of the I/O device 108, the registers 136 of the AU 110, or the AU memory 134, respectively. As another example, to access the system memory 106 without using the CPU 102, the I/O device 108, the AU 110, or both are configured to issue one or more DMA requests. Such DMA requests each request access to read, write, fetch, or pre-fetch data residing at one or more virtual addresses (e.g., device virtual addresses) which each represent at least a portion of the system memory 106. Based on receiving an MMIO request or DMA request, the IOMMU 148 is configured to translate the virtual address indicated in the MMIO or DMA request to a physical address and fulfill the request.

In variations, the processing system 100 can include any combination of the components depicted and described. For example, in at least one variation, the processing system 100 does not include one or more of the components depicted and described in relation to FIG. 1. Additionally or alternatively, in at least one variation, the processing system 100 includes additional and/or different components from those depicted. The processing system 100 is configurable in a variety of ways with different combinations of components in accordance with the described techniques.

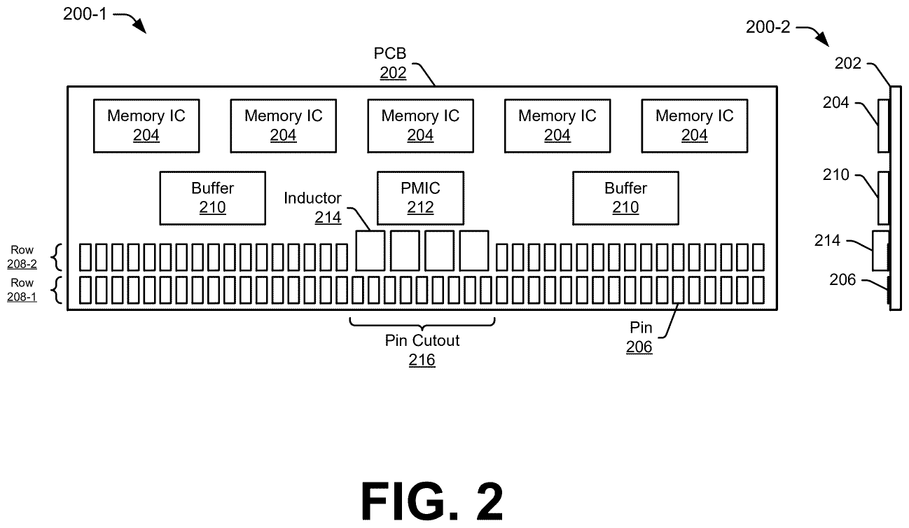

FIG. 2 depicts a non-limiting example of a pin cutout in a memory module from a top view 200-1 and a side view 200-2. The figure illustrates the implementation of a pin cutout in a memory module that enables efficient component placement while maintaining necessary electrical connectivity.

A memory module, such as a DIMM, is a circuit board (e.g., a printed circuit board (PCB) 202) on which volatile memory and/or non-volatile memory are mounted. In other implementations, the memory module is a Transflash memory module, a single in-line memory module (SIMM), or another type of memory module incorporated into the PCB 202. The volatile memory and the non-volatile memory correspond to semiconductor memory, where data is stored within memory cells on one or more memory integrated circuits (ICs) 204. The memory ICs 204 can be arranged in a specific pattern on the PCB 202 to optimize signal integrity, power delivery, and thermal management.

Broadly, the volatile memory retains data as long as a device is connected to power, and the data is accessible relatively faster than the non-volatile memory. Examples of volatile memory include random-access memory (RAM), dynamic random-access memory (DRAM), synchronous dynamic random-access memory (SDRAM), and static random-access memory (SRAM). For example, the memory ICs 204 are volatile memory that utilize double data rate (DDR) memory technology (e.g., DDR, DDR2, DDR3, DDR4, DDR5, and/or DDR6 technology). The DDR6 technology, in particular, may require additional pins for improved signal integrity and power delivery, necessitating innovations in the physical design of memory modules to accommodate these additional connections while maintaining the established form factor.

The non-volatile memory retains data even after the device is disconnected from power, but is accessible relatively more slowly than the volatile memory. Examples of non-volatile memory include solid state disks (SSDs), flash memory, read-only memory (ROM), programmable read-only memory (PROM), erasable programmable read-only memory (EPROM), and electronically erasable programmable read-only memory (EEPROM). While the present implementation primarily focuses on volatile memory configurations, the pin cutout techniques described herein are equally applicable to modules incorporating non-volatile memory components or other technologies.

As described above, memory modules, such as DIMMs, include the PCB 202 with various components, including, as a non-limiting example, one or more memory ICs 204, multiple pins 206, one or more buffers 210, a power manager IC (PMIC) 212, and one or more inductors 214. The PCB 202 is a physical board that houses the memory ICs 204 and provides the necessary connections. The memory ICs 204 are the storage elements on the PCB 202 where data is stored. In some implementations, the memory ICs are arranged in a two-dimensional or three-dimensional grid on the PCB 202. The pins 206 are generally gold-plated contacts that connect the DIMM or other memory module to the motherboard's memory slots, ensuring a reliable electrical connection. The buffers 210 temporarily store data being read from or written to the memory ICs 204. The PMIC 212 regulates the power supply to the DIMM or other memory module to ensure operation at the correct voltage and current levels. The inductors 214 filter or suppress electrical noise or store energy to regulate the power on one or more power rails on the PCB 202. The inductors 214 are typically larger and taller components compared to other elements on the PCB 202, which presents challenges for component placement and airflow management. Although not illustrated, the PCB 202 often includes an address decoder to decode the address signals received from the motherboard to select the appropriate memory IC 204, a clock generator to generate the clock signals that control the timing of operations with the DIMM, capacitors, and resistors, power rails, and other componentry.

As described above, DIMMs currently include a single row of pins. However, as the memory technology advances (e.g., to DDR6) and additional components are added to the memory modules, additional pins rows will be added to the PCB 202. For example, FIG. 2 illustrates a first row 208-1 and a second row 208-2 of pins 206. In other implementations, the PCB 202 may include additional pin rows, including three or four pin rows. Because the size of the PCB 202 is held constant, the introduction of the second row 208-2 (or additional rows) of pins 206 decreases the available area on the PCB 202 for mounting components on a single side. This constraint creates a design challenge where component placement is optimized within the limited available space while maintaining proper electrical and thermal performance.

To avoid placing larger components on the back side of PCB 202 and recapturing some board area, the described techniques provide a pin cutout 216 in the second row 208-2. The pin cutout 216 removes or avoids adding a number of pins 206 to the second row 208-2. In the illustrated example, the pin cutout 216 is positioned near the center of the second row 208-2, allowing the inductors 214 to be positioned near the PMIC 212. In other implementations, the pin cutout 216 is positioned in a different relative position of the second row 208-2. In yet other implementations, PCB 202 may include additional pin cutouts 216 (e.g., two, three, or four pin cutouts 216). In any of these implementations, the pin cutouts 216 can have different sizes (e.g., remove a different number of pins 206), different depths (e.g., removing pins from both the first row 208-1 and the second row 208-2), and different relative placements (e.g., relative to the edges of the PCB 202). The pin cutout 216 may have a variable width along its length to accommodate different component sizes or arrangements. In the illustrated example, the inductors 214 are positioned in the pin cutout 216. In other implementations, different components (e.g., the PMIC 212 or buffers 210) can be positioned in the pin cutout 216. The specific configuration of the pin cutout 216 can be customized based on the particular components that need to be accommodated, as well as their respective sizes and thermal characteristics.

As illustrated in side view 200-2, the taller inductors 214 are placed in the pin cutout 216, which allows the generally taller inductors 214 to partially hide in the shadow of the connector and minimize their impact on airflow. In this way, the airflow obstruction of taller components (e.g., the inductors 214) is minimized by placing them near the DIMM connector or, at the very least, partially enveloped and hidden by the connector. In addition, the pin cutout 216 provides an extra area on the top side of the PCB 202, potentially avoiding the need to place larger or taller components on the bottom side of the PCB 202, which may require additional spacing between DIMMs and/or obstruct the inclusion of heat transfer plates between DIMMs. This arrangement enables more efficient cooling of the memory module by allowing better airflow across the PCB surface, especially for densely packed computing environments. The placement of components within the pin cutout 216 also allows for more uniform component heights on the PCB 202, which can simplify heat spreader designs and enable tighter stacking of multiple DIMMs.

Traditionally, the power pins that provide the power supply to the DIMM are located at or near both lateral edges of the first row 208-1. The described techniques provide the power pins near the lateral center of the first row 208-1 (or another pin row) to reduce the length of power rails from the power pins to the PMIC 212 and/or the inductors 214. This centralized placement of power pins enhances power delivery efficiency by minimizing the distance that power travels from the pins to the PMIC 212, thereby reducing power loss and improving signal integrity. The shorter power rails also reduce electromagnetic interference (EMI) and improve the overall electrical performance of the memory module. Additionally, this arrangement allows for more efficient power distribution across the PCB 202, particularly when multiple memory ICs 204 are present.

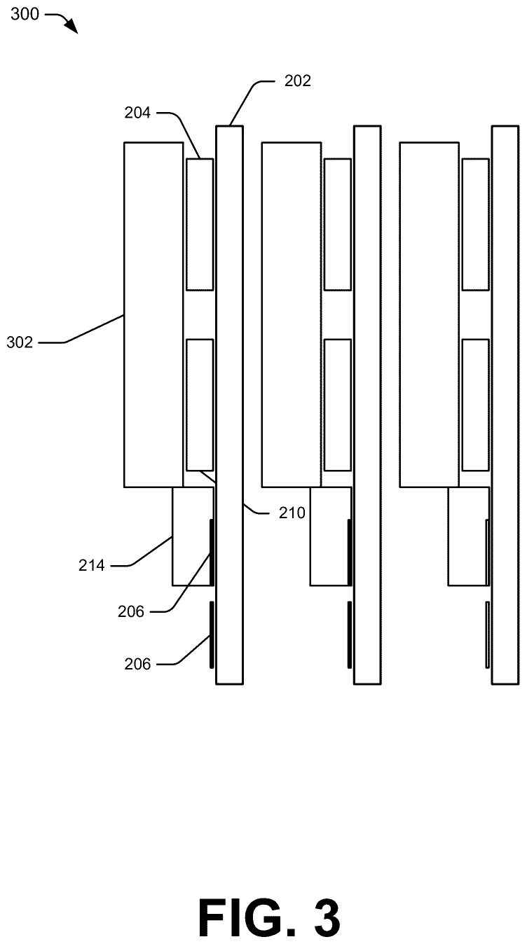

FIG. 3 depicts a non-limiting example 300 of multiple DIMMs with pin cutouts in a stacked arrangement. In the illustrated example 300, three DIMMs are arranged in a stack near one another. Here, the DIMMs are arranged in a lateral stack; however, in other implementations, multiple DIMMs may be arranged in a vertical stack, a two-dimensional stack arrangement (e.g., a grid of vertical stacks), or in other manners. The stacked arrangement demonstrates how the pin cutout design enables more efficient use of space in memory-intensive systems where multiple DIMMs are installed in close proximity. The consistent placement of pin cutouts across multiple DIMMs ensures compatibility with standardized motherboard connectors while maintaining the benefits of the improved component placement.

As described with respect to FIG. 2, each DIMM includes a PCB 202, one or more memory ICs 204, pins 206, buffers 210, PMIC 212 (not illustrated in FIG. 3), and inductors 214. Connected to or arranged near each DIMM is a heat transfer plate 302, which manages the temperature of the DIMM components and board, and facilitates heat transfer away from the DIMM. By placing the taller inductors 214 in the pin cutouts 208, the heat transfer plates 302 can be placed relative to a single side of each DIMM and the individual DIMMs can be placed in a tighter stack. In other implementations, the heat transfer plate 302 may have a different profile, shape, or coverage. For example, in another implementation, the heat transfer plate 302 can partially cover the inductors 214.

The heat transfer plates 302 can be made of various thermally conductive materials such as aluminum, copper, or composite materials designed to efficiently dissipate heat. The placement of the heat transfer plates 302 relative to the DIMMs is optimized to ensure maximum thermal conductivity while maintaining proper clearance for the components positioned within the pin cutouts. This arrangement can significantly improve thermal management in high-density memory configurations, which is particularly useful for high-performance computing applications where memory modules operate at elevated temperatures.

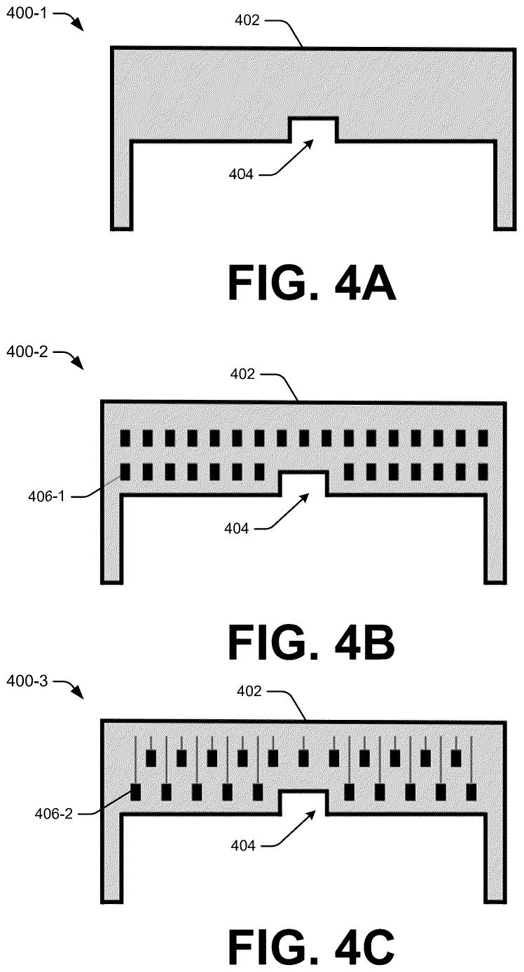

FIGS. 4A through 4C depict various views of example motherboard connectors to receive a memory module with a pin cutout.

FIG. 4A illustrates a top view 400-1 of a motherboard connector 402. The motherboard connector 402 includes a housing configured to receive a memory module with a pin cutout and facilitate the connection of the memory module (e.g., a DIMM) to a motherboard. The connector 402 incorporates a connector cutout 404 that is designed to align with the pin cutout 216 on the PCB 202 when the memory module is inserted into the connector 402. This top view 400-1 provides a visual representation of the overall shape and structure of the motherboard connector 402, including the position of the connector cutout 404 within the connector design in one example implementation. This top view 400-1 illustrates how the connector cutout 404 provides space to accommodate components such as inductors 214 that are positioned within the pin cutout 216 of the PCB 202.

FIG. 4B illustrates a first cross-section view 400-2 of the motherboard connector 402 with connector pins 406-1 arranged in one or more rows within the housing. The connector pins 406-1 are configured to electrically engage with corresponding pins 206 on the memory module. The connector cutout 404 creates a gap in one row of connector pins 406-1, which is designed to align with the pin cutout 216 on the PCB 202. The connector cutout 404 may be positioned near the lateral center of the row of connector pins 406-1 to align with centrally located components on the memory module.

FIG. 4C illustrates a second cross-section view 400-3 of an alternative motherboard connector 402 design featuring connector prongs 406-2. This alternative design maintains the connector cutout 404 that aligns with the pin cutout 216 on the PCB 202, but utilizes a different type of electrical contact mechanism. The motherboard connector 402 is specifically designed to align with the pin configuration of the memory module, including the pin cutout 216, ensuring proper electrical connectivity while accommodating the physical arrangement of components on the PCB 202. The connector cutout 404 in this design may have a variable depth along the length of two rows of connector prongs 406-2 to accommodate components of different heights on the memory module. This complementary design between the memory module and the connector 402 ensures that the taller components positioned within the pin cutout 216 can be partially recessed into the connector 402 when the DIMM is inserted, maximizing space utilization while maintaining proper electrical connections.

In both connector designs illustrated in FIGS. 4B and 4C, the electrical contacts (either connector pins 406-1 or connector prongs 406-2) may be arranged in at least two rows, with a subset of contacts in a first row configured to provide power to the memory module and positioned near a lateral center of the first row to align with the centralized power pins on the memory module. The electrical contacts are arranged in one or more rows within the housing and configured to electrically engage with corresponding pins of the memory module.

The connector cutout 404 provides space to accommodate one or more components on the memory module, particularly taller components such as inductors 214. The connector cutout 404 may extend across one or more rows of electrical contacts, depending on the specific component arrangement on the memory module. In other implementations, the connector cutout 404 is located in one or more other locations along the motherboard connector 402 to match the placement of pin cutouts 216 on the PCB 202. The connector cutout 404 may be positioned near a lateral center of the at least one row of electrical contacts to align with centrally located components on the memory module.

In some implementations, the plurality of electrical contacts are arranged in at least two rows, and the connector cutout 404 provides space to accommodate one or more components on the memory module, particularly taller components such as inductors 214. The connector cutout 404 may extend across one or more rows of electrical contacts, depending on the specific component arrangement on the memory module.

The housing of the connector 402 is designed to securely hold the memory module while ensuring proper alignment of the electrical contacts with the corresponding pins on the memory module, even with the presence of the connector cutout 404. The connector 402 may be implemented in a system comprising one or more memory modules and one or more motherboard connectors, where each connector is specifically configured to align with the pin configuration of its corresponding memory module.

The various functional units illustrated in the figures and/or described herein (including, where appropriate, the PCB 202) are implemented in any of a variety of different manners such as hardware circuitry, software or firmware executing on a programmable processor, or any combination of two or more of hardware, software, and firmware. The methods provided are implemented in any of a variety of devices, such as a general-purpose computer, a processor, or a processor core.

What is claimed is:

1. A memory module, comprising:
one or more memory integrated circuits mounted on a printed circuit board (PCB);
one or more additional components mounted on the PCB; and
one or more rows of pins for electrically connecting the memory module to a motherboard, the one or more rows including a pin cutout that discontinues the one or more rows.

2. The memory module of claim 1, wherein the PCB includes at least two rows of pins.

3. The memory module of claim 2, wherein the pin cutout includes multiple is provided in a single row of the at least two rows of pins.

4. The memory module of claim 2, wherein:
the PCB includes at least three rows of pins; and
the pin cutout extends across at least two of the at least three rows of pins.

5. The memory module of claim 1, wherein the one or more rows include multiple pin cutouts.

6. The memory module of claim 1, wherein the pin cutout is centrally located in relation to the one or more rows.

7. The memory module of claim 1, wherein the memory module is a dual in-line memory module (DIMM).

8. The memory module of claim 1, wherein the one or more memory integrated circuits comply with a double data rate six (DDR6) memory specification.

9. The memory module of claim 1, wherein the pin cutout is configured to accommodate placement of multiple additional components.

10. The memory module of claim 9, wherein the multiple additional components positioned at least partially in the pin cutout include one or more inductors.

11. The memory module of claim 9, wherein the pin cutout is configured to accommodate the placement of the multiple additional components to be partially recessed into a portion of a motherboard connector when the memory module is inserted into the motherboard connector.

12. The memory module of claim 9, wherein the pin cutout has a variable width along a length of two or more rows of pins to accommodate the placement of different sizes or arrangements of the one or more additional components.

13. The memory module of claim 1, wherein power pins are positioned near a lateral center of at least one of the one or more rows of pins to reduce a length of power rails from the power pins to a power management integrated circuit (PMIC).

14. A motherboard connector comprising:
a housing configured to receive a memory module;
a plurality of electrical contacts arranged in one or more rows within the housing, the plurality of electrical contacts configured to electrically engage with corresponding pins of the memory module; and
a cutout region in at least one row of the plurality of electrical contacts, the cutout region configured to align with a pin cutout in a corresponding row of pins on the memory module when the memory module is inserted into the housing.

15. The motherboard connector of claim 14, wherein the cutout region provides space to accommodate one or more components on the memory module.

16. The motherboard connector of claim 14, wherein the cutout region provides space to accommodate an inductor on the memory module.

17. The motherboard connector of claim 14, wherein the cutout region is positioned away from a lateral center of the at least one row of electrical contacts.

18. The motherboard connector of claim 14, wherein:
the plurality of electrical contacts are arranged in at least two rows; and
a subset of electrical contacts in a first row are configured to provide power to the memory module and are positioned near a lateral center of the first row.

19. The motherboard connector of claim 14, wherein the cutout region has a variable depth along a length of two rows of electrical contacts to accommodate components of different heights on the memory module.

20. A system comprising:
one or more memory modules, each memory module including:
one or more memory integrated circuits mounted on a printed circuit board (PCB);
one or more additional components mounted on the PCB; and
one or more rows of pins for electrically connecting the memory module to a motherboard, the one or more rows including a pin cutout that discontinues the one or more rows; and
one or more motherboard connectors of the motherboard, each motherboard connector including:
a housing configured to receive the memory module;
a plurality of electrical contacts arranged in one or more rows within the housing, the plurality of electrical contacts configured to electrically engage with corresponding pins of the memory module; and
a cutout region in at least one row of the plurality of electrical contacts, the cutout region configured to align with the pin cutout in a corresponding row of pins on the memory module when the memory module is inserted into the housing.
